(19) United States
(12) Patent Application Publication
(10) Pub. No.: US 2010/0052776 A1
(43) Pub. Date: Mar. 4, 2010

(54) INTERNAL VOLTAGE GENERATING CIRCUIT

(75) Inventor: Kwang-Su LEE, Gyeonggi-do (KR)

Correspondence Address: IP & T Law Firm PLC, 7700 Little River Turnpike, Suite 207, Annandale, VA, 22003, US

(73) Assignee: HYNIX SEMICONDUCTOR, INC., Gyeonggi-do (KR)

(21) Appl. No.: 12/345,620

(22) Filed: Dec. 29, 2008

(30) Foreign Application Priority Data
Sep. 1, 2008 (KR) 10-2008-0085849

(51) Int. Cl. G11C 5/14

(52) U.S. Cl. 327/548

(57) ABSTRACT

An internal voltage generating circuit includes an oscillation unit configured to generate an oscillation signal, and to change a period of the oscillation signal according to whether is in a burn-in test mode; and a negative voltage pumping unit configured to generate a negative voltage in response to the oscillation signal.

### CROSS-REFERENCE TO RELATED APPLICATIONS

The present invention claims priority of Korean patent application number 10-2008-0085849, filed on Sep. 1, 2008, which is incorporated by reference in its entirety.

### BACKGROUND OF THE INVENTION

The present invention relates to an internal voltage generating circuit for use in a semiconductor memory device, and more particularly, to an internal voltage generating circuit for stably generating an internal voltage in a burn-in test.

Generally, semiconductor memory devices use not only an external power supply voltage but also an internal voltage generated in the semiconductor memory devices whose voltage level is different from a voltage level of the external power supply voltage. For instance, a semiconductor memory device, e.g., a Dynamic Random Access Memory (DRAM), internally generates a high voltage VPP higher than a power supply voltage VDD, a negative voltage VBB lower than a ground voltage VSS and a core voltage VCORE used in a core area of the semiconductor memory device.

In order to generate the internal voltage, a down converting method for generating the core voltage VCORE and a charge pumping method for generating the high voltage VPP and the negative voltage VBB are used. The charge pumping method related to the present invention is described below.

FIG. 1 is a block diagram depicting a conventional internal voltage generating circuit for generating a negative voltage.

As shown in the drawing, the conventional internal voltage generating circuit includes a negative-voltage detection unit 10, an oscillation unit 20 and a negative-voltage pumping unit 30.

The negative-voltage detection unit 10 generates a detection signal BBWEB for determining whether the negative-voltage pumping unit 30 is operated or not as a part to detect the level of a negative voltage VBB. When the level of the negative voltage VBB is higher than a predetermined level, i.e., the level of the negative voltage VBB is not sufficiently low, the detection signal BBWEB is activated and outputted. On the other hand, when the level of the negative voltage VBB is lower than the predetermined level, the detection signal BBWEB is deactivated and outputted.

The oscillation unit 20 outputs an oscillation signal OSC in response to the detection signal BBWEB. The oscillation unit 20 outputs the oscillation signal OSC when the detection signal BBWEB is inputted being activated; however, the oscillation unit 20 does not output the oscillation signal OSC when the detection signal BBWEB is inputted being deactivated.

The negative-voltage pumping unit 30 pumps the negative voltage VBB in response to the oscillation signal OSC. Since the pumping operation is periodically performed according to the oscillation signal OSC, a period of the oscillation signal OSC determines the speed of the pumping operation. The negative-voltage pumping unit 30 includes a pumping control unit 31 and a charge pumping unit 32. The pumping control unit 31 generates pumping control signals P1, P2, G1 and G2 in response to the oscillation signal OSC. The charge pumping unit 32 pumps the negative voltage VBB in response to the pumping control signals P1, P2, G1 and G2.

Although it has been described that the negative-voltage pumping unit 30 exemplified in the drawing generates the pumping control signals P1, P2, G1 and G2 using the oscillation signal OSC and pumps the negative voltage VBB according to the pumping control signals P1, P2, G1 and G2, a construction of the negative-voltage pumping unit 30 can be variously designed. For instance, the charge pumping unit 32 can be designed to perform the pumping operation by directly receiving the oscillation signal OSC.

No matter how the negative-voltage pumping unit 30 is designed, the pumping operation should be periodically performed. Therefore, the negative-voltage pumping unit 30 still needs the oscillation signal OSC.

FIG. 2 is a detailed circuit diagram illustrating the negative-voltage detection unit 10 shown in FIG. 1.

The negative-voltage detection unit 10 includes first and second transistors P01 and P02. Referring to the drawing, a ground voltage VSS and the negative voltage VBB are respectively applied to a gate of the first transistor P01 and a gate of the second transistor P02. The first and second transistors P01 and P02 are operated in a linear region and divides a high voltage VCORE and the ground voltage VSS by acting as a resistor. For instance, when the absolute value of the negative voltage VBB is low, i.e., the voltage level of the negative voltage VBB is high, the resistance of the second transistor P02 is increased and thus the voltage level loaded on a node DET is increased. Accordingly, the detection signal BBWEB is activated as a low level and outputted from an inverter I03. In this case, the negative voltage is pumped.

On the contrary, when the absolute value of the negative voltage VBB is high, i.e., the level of the negative voltage VBB is low, the resistance of the second transistor P02 is decreased and thus the voltage level loaded on the node DET is decreased. Therefore, the detection signal BBWEB is deactivated as a high level. In this case, the negative voltage pumping is stopped.

In short, the negative-voltage detection unit 10 detects the level of the negative voltage VBB according to the voltage distribution of the first and second transistors P01 and P02 which receive the ground voltage VSS and the negative voltage VBB respectively.

For reference, although the core voltage VCORE is shown as an example of a high voltage, a high voltage higher than the ground voltage VSS and other high voltages, e.g., VDD and VREFB, can all be used.

FIG. 3 is a detailed circuit diagram showing the oscillation unit 20 shown in FIG. 1.

As shown in the drawing, the oscillation unit 20 can be constructed with a ring oscillator having inverters and a NOR gate for receiving the detection signal BBWEB.

When the detection signal BBWEB is inputted as a high level to the NOR gate, the NOR gate always outputs a low signal. When the detection signal BBWEB is inputted as a low level to the NOR gate, the NOR gate is operated as an inverter so that the oscillation signal OSC having a constant period is generated through inverters connected in a ring form.

That is, the oscillation unit 20 outputs the oscillation signal OSC having a constant period while the detection signal BBWEB is activated as a low level.

FIG. 4 is a detailed circuit diagram depicting the pumping control unit 31 shown in FIG. 1. FIG. 5 is a timing diagram showing an operation of the pumping control unit 31 shown in FIG. 4.

As shown in the drawings, the pumping control unit 31 includes NAND and NOR gates and a plurality of inverters in order to generate the control signals P1, P2, G1 and G2 for controlling the charge pumping unit 32. The control signals P1 and P2 drive the charge pumping unit 32 to perform the pumping operation and the control signals G1 and G2 are a precharge signals.

FIG. 6 is a detailed circuit diagram illustrating the charge pumping unit 32 shown in FIG. 1.

As shown in the drawing, the charge pumping unit 32 plays a role of pumping the negative voltage VBB and includes a plurality of p-type metal oxide semiconductor (PMOS) transistors each of which is operated as a capacitor for receiving the control signals P1, P2, G1 and G2. Each drain and source of the PMOS transistors are connected to each other in order to receive the control signals P1, P2, G1 and G2 through the connected node.

Briefly describing an operation of the charge pumping unit 32, the pumping operation of the negative voltage VBB is performed by inputting the control signals P1 and P2, and voltages loaded on nodes A and B are precharged by inputting the control signals G1 and G2.

FIG. 7 is a block diagram showing a conventional high voltage pumping circuit.

The conventional high voltage pumping circuit includes a high-voltage detection unit 40, an oscillation unit 50 and a high-voltage pumping unit 60. Operations of the units included in the conventional high voltage pumping circuit are similar to those of the units included in the conventional negative voltage pumping circuit shown in FIG. 1. However, there may be some modifications for pumping a high voltage VPP instead of the negative voltage VBB.

The high-voltage detection unit 40 detects the level of the high voltage VPP in order to generate a detection signal PPES for determining whether the high-voltage pumping unit 60 is operated or not. The oscillation unit 50 receives the detection signal PPES to generate an oscillation signal OSC. The high-voltage pumping unit 60 pumps the high voltage VPP in response to the oscillation signal OSC outputted from the oscillation unit 50. The high-voltage pumping unit 60 may include a pumping control unit 61 and a charge pumping unit 62. In detail, the pumping control unit 61 generates pumping control signals P1, P2, G1 and G2 in response to the oscillation signal OSC and the charge pumping unit 62 pumps the high voltage VPP in response to the control signals P1, P2, G1 and G2.

Briefly explaining an overall operation of the conventional high voltage pumping unit, when the level of the high voltage VPP detected by the high-voltage detection unit 40 is sufficiently high, the pumping operation is stopped; however, when the level of the high voltage VPP detected by the high-voltage detection unit 40 is low, the high-voltage pumping unit 60 performs the high voltage pumping operation.

FIG. 8 is a detailed circuit diagram depicting the high-voltage detection unit 40 shown in FIG. 7.

The high-voltage detection unit 40 distributes the high voltage VPP feedbacked from the high-voltage pumping unit 60 in order to detect the voltage level of the high voltage VPP by comparing the divided voltage with a reference voltage VREFP. That is, when the high voltage VPP becomes lower than a required target level, the voltage loaded on a node C becomes lower than the reference voltage VREFP. Then, a transistor N02 forming a current mirror is more strongly turned on than a transistor N01 so that the logic level on a node D becomes low. Accordingly, the detection signal PPES is activated as a high level and is outputted from an inverter I20. As a result, the high voltage pumping operation is performed.

On the contrary, when the high voltage VPP is higher than the required target level, the voltage loaded on the node C is higher than the reference voltage VREFP. In this case, the logic level on the node D becomes high and thus the detection signal PPES outputted from the inverter I20 is deactivated as a low level. As a result, the high voltage pumping operation is stopped.

FIG. 9 is a detailed circuit diagram depicting the oscillation unit 50 shown in FIG. 7.

As shown in the drawing, the oscillation unit 50 is constructed in the shape of a ring oscillator by including inverters and a NAND gate for receiving the detection signal PPES. The oscillation unit 50 of FIG. 9 basically has a ring oscillator form like the oscillation unit 20 shown in FIG. 3. However, since the detection signal PPES is activated as a high level unlike the detection signal BBWEB, the NAND gate is used instead of the NOR gate.

When the detection signal PPES is inputted as a low level to the NAND gate, the NAND gate always outputs a low signal. When the detection signal PPES is inputted as a high level to the NAND gate, the NAND gate is operated as an inverter so that the oscillation signal OSC having a constant period is generated through inverters connected in a ring form.

FIG. 10 is a detailed circuit diagram showing the pumping control unit 61 shown in FIG. 7 and FIG. 11 is a timing diagram illustrating the operation of the pumping control unit 61.

As shown in the drawings, the pumping control unit 61 includes NAND and NOR gates and a plurality of inverters in order to output the control signals P1, P2, G1 and G2 for controlling the charge pumping unit 62. The control signals P1 and P2 are signals to drive the charge pumping unit 62 to perform the pumping operation and the control signals G1 and G2 are a precharge signals.

The timing to generate the control signals P1, P2, G1 and G2 according to the oscillation signal OSC is illustrated in FIG. 11. Herein, the timing diagram shown in FIG. 11 is different from the timing diagram shown in FIG. 5 since the pumping operation is performed not for the negative voltage VBB but for the high voltage VPP.

FIG. 12 is a detailed circuit diagram showing the charge pumping unit 62 shown in FIG. 7.

As shown in the drawing, the charge pumping unit 62 plays a role of generating the high voltage VPP and is constructed by including a plurality of n-type metal oxide semiconductor (NMOS) transistors each of which is operated as a capacitor for receiving the control signals P1, P2, G1 and G2. Each drain and source of the NMOS transistors are connected each other in order to receive the control signals P1, P2, G1 and G2 through the connected node.

Briefly describing an operation of the charge pumping unit 62, the pumping operation of the high voltage VPP is performed by inputting the control signals P1 and P2 and voltages loaded on nodes E and F are precharged by inputting the control signals G1 and G2.

A burn-in test is performed by giving the maximum stress to a semiconductor device in order to find out whether the semiconductor device can endure the stress or not. In the burn-in test, the power supply voltage VDD is adjusted to a high level and several operations are performed at the same time.

For instance, in case of testing a semiconductor memory device, the power supply voltage VDD is increased to be higher than that of a normal mode and more word lines are activated simultaneously so that the semiconductor memory device is overly operated. Therefore, in the burn-in test, the semiconductor memory device consumes much more power supply voltages, including the pumping voltages VPP and VBB.

Since the power supply voltage VDD applied to the semiconductor memory device is power applied from the outside, the power supply voltage VDD can be sufficiently applied to the semiconductor memory device even in the burn-in test by applying a strong power supply voltage to the semiconductor memory device from the outside. However, since the pumping voltages VPP and VBB are internally generated, it is impossible to externally apply strong pumping voltages in the burn-in test from the outside. Therefore, the internal voltage generating circuit should generate stronger pumping voltages. However, according to the related art, the conventional internal voltage generating circuits as shown in FIGS. 1 and 7 perform the same operation in the normal mode and the burn-in test mode. Accordingly, the conventional internal voltage generating circuit cannot satisfy the above-mentioned requirement.

Therefore, an internal voltage generating circuit is required that is capable of generating an adequate pumping voltage matching the status of the burn-in test.

### SUMMARY OF THE INVENTION

Embodiments of the present invention are directed to provide an internal voltage generating circuit capable of supplying stable pumping voltages VPP and VBB even in a burn-in test state.

In accordance with an aspect of the present invention, there is provided an internal voltage generating circuit, which includes: an oscillation unit configured to generate an oscillation signal and to change a period of the oscillation signal according to whether in a burn-in state; and a negative voltage pumping unit configured to generate a negative voltage in response to the oscillation signal.

In accordance with another aspect of the present invention, there is provided an internal voltage generating circuit, which includes: an oscillation unit configured to generate an oscillation signal, and to change a period of the oscillation signal according to whether is in a burn-in test state; and a high voltage generation unit configured to generate a high voltage higher than a power supply voltage in response to the oscillation signal.

### BRIEF DESCRIPTION OF THE DRAWINGS

FIG. 1 is a block diagram depicting a conventional internal voltage generating circuit for generating a negative voltage.

FIG. 2 is a detailed circuit diagram illustrating a negative voltage detection unit 10 shown in FIG. 1.

FIG. 3 is a detailed circuit diagram showing an oscillation unit 20 shown in FIG. 1.

FIG. 4 is a detailed circuit diagram depicting a pumping control unit 31 shown in FIG. 1.

FIG. 5 is a timing diagram showing an operation of the pumping control unit 31 shown in FIG. 4.

FIG. 6 is a detailed circuit diagram illustrating a charge pumping unit 32 shown in FIG. 1.

FIG. 7 is a block diagram showing a conventional high voltage pumping circuit.

FIG. 8 is a detailed circuit diagram depicting a high voltage detection unit 40 shown in FIG. 7.

FIG. 9 is a detailed circuit diagram depicting an oscillation unit 50 shown in FIG. 7.

FIG. 10 is a detailed circuit diagram showing a pumping control unit 61 shown in FIG. 7.

FIG. 11 is a timing diagram illustrating an operation of the pumping control unit 61 shown in FIG. 7.

FIG. 12 is a schematic circuit diagram showing a charge pumping unit 62 shown in FIG. 7.

FIG. 13 is a block diagram depicting an internal voltage generating circuit for generating a negative voltage in accordance with an embodiment of the present invention.

FIG. 14 is a schematic diagram depicting a first embodiment of the oscillation unit 1320 shown in FIG. 13.

FIG. 15 is a schematic diagram depicting a second embodiment of the oscillation unit 1320 shown in FIG. 13.

FIG. 16 is a schematic diagram illustrating a third embodiment of the oscillation unit 1320 shown in FIG. 13.

FIG. 17 is a block diagram showing an internal voltage generating circuit for generating a high voltage in accordance with an embodiment of the present invention.

### DESCRIPTION OF SPECIFIC EMBODIMENTS

In order to describe the present invention in detail such that those skilled in the art easily implement the spirit and scope of the present invention, the embodiment of the present invention will be described with reference to the accompanying drawings.

FIG. 13 is a block diagram depicting an internal voltage generating circuit for generating a negative voltage in accordance with an embodiment of the present invention.

The internal voltage generating circuit includes a negative-voltage detection unit 1310, an oscillation unit 1320 and a negative-voltage pumping unit 1330.

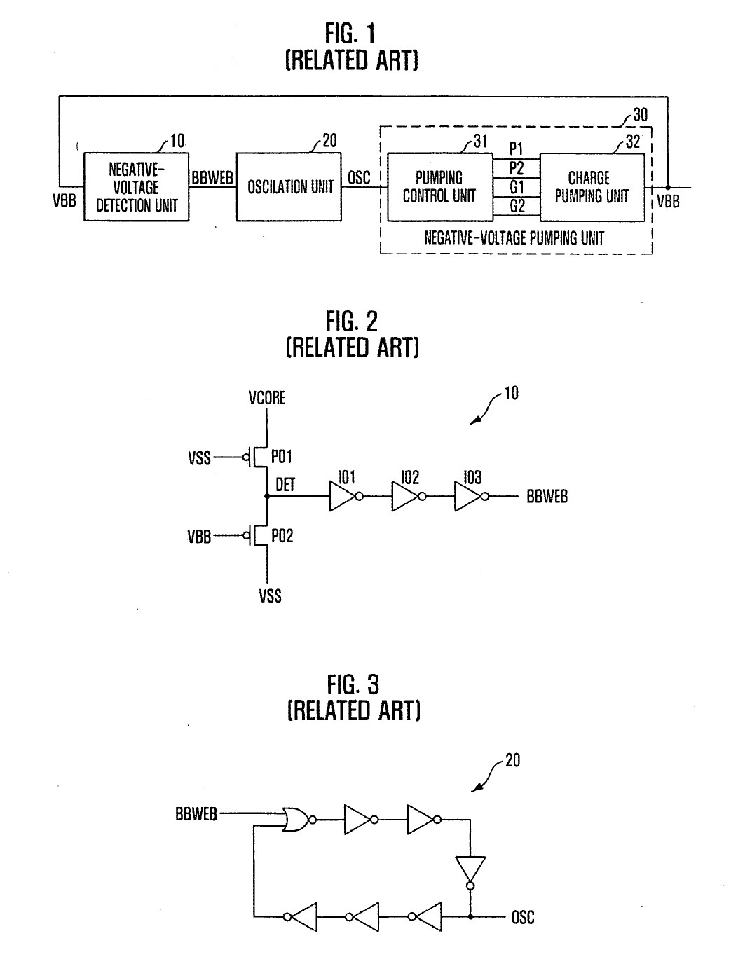

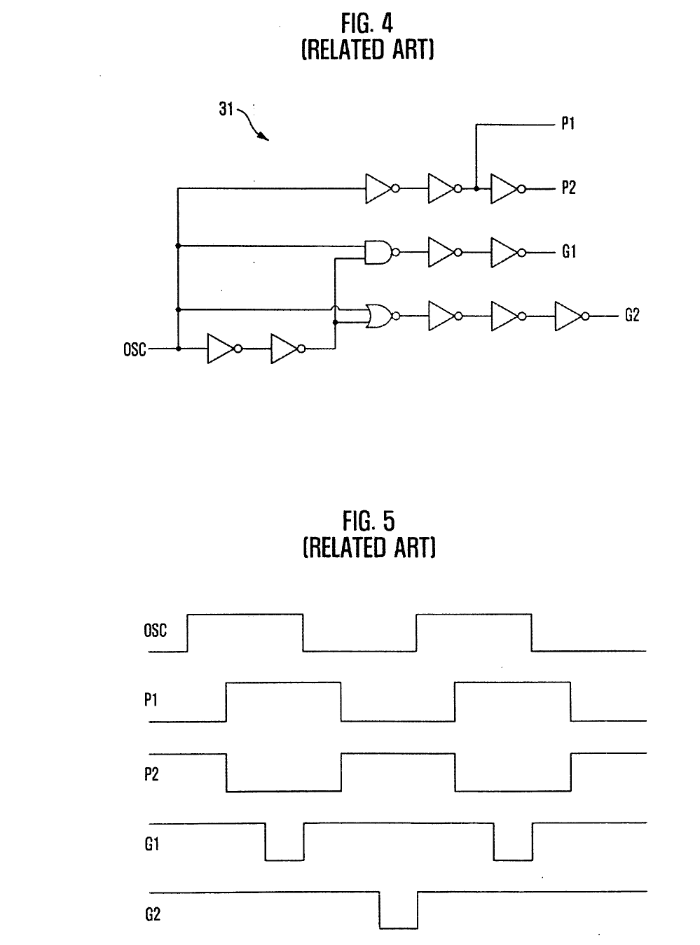

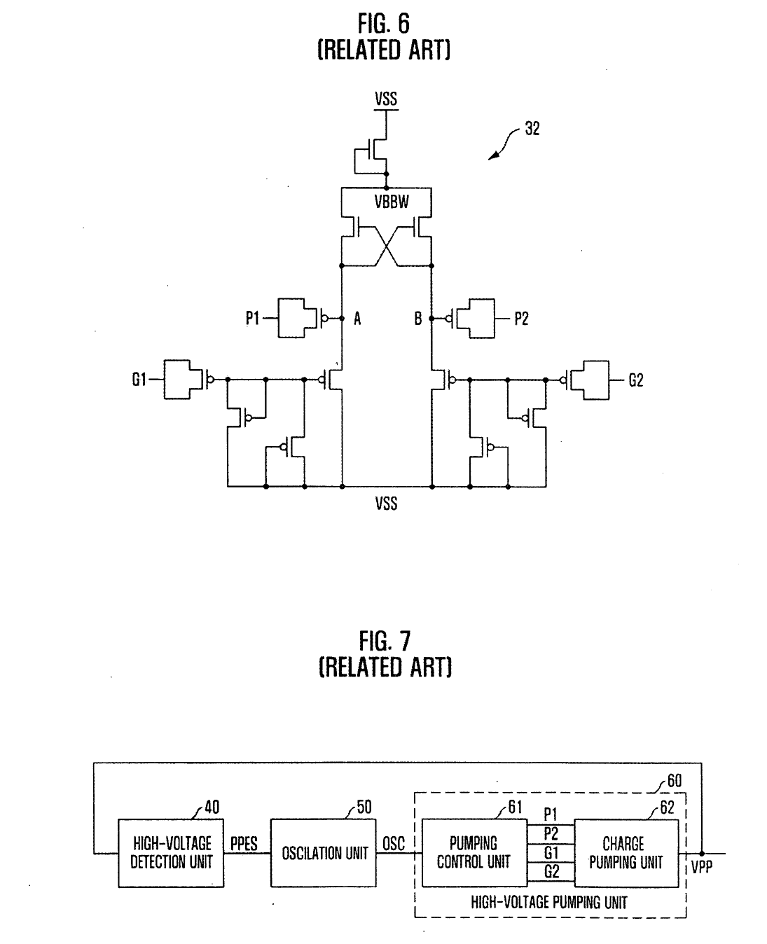

The negative-voltage detection unit 1310 activates a detection signal BBWEB to output the activated result when the level of a negative voltage VBB is not sufficiently low. The detection signal BBWEB is activated means that an oscillation signal OSC is outputted from the oscillation unit 1320, and the detection signal BBWEB is deactivated means that the oscillation signal OSC is not outputted from the oscillation unit 1320. The negative-voltage detection unit 1310 can be similarly designed with the conventional negative-voltage detection unit 10 shown in FIG. 1.

The negative-voltage detection unit 1310 is employed to pump the negative voltage VBB only when the negative voltage generating circuit is needed to the pumping of the negative voltage VBB. Therefore, if the internal voltage generating circuit is designed to always pump the negative voltage VBB, the internal voltage generating circuit can be operated without the negative-voltage detection unit 1310.

The oscillation unit 1320 outputs the oscillation signal OSC when the detection signal BBWEB is activated and does not output the oscillation signal OSC when the detection signal BBWEB is deactivated. The conventional oscillation unit 20 shown in FIG. 1 always outputs the oscillation signal OSC having a constant period whenever the detection signal BBWEB is activated. However, in accordance with the preferred embodiment of the present invention, the oscillation unit 1320 adjusts a period of the oscillation signal OSC according to whether the internal voltage generating circuit is in a burn-in test state.

In the burn-in test state, the period of the oscillation signal OSC is adjusted to be decreased, i.e., the frequency is increased, so that the negative voltage pumping operation can be fast performed. When not in the burn-in test state, the period of the oscillation signal OSC is adjusted to be increased, i.e., the frequency is decreased, so that the negative voltage pumping operation can be more slowly performed than in the burn-in test mode. A signal BI of the drawing represents a signal to be activated during the burn-in test.

The negative-voltage pumping unit 1330 generates the negative voltage VBB in response to the oscillation signal OSC. The negative voltage VBB is generated by the pumping operation. Herein, the speed of the negative voltage pumping operation is changed according to the period of the oscillation signal OSC. The negative-voltage pumping unit 1330 can be similarly constructed with the conventional negative-voltage pumping unit 30 shown in FIG. 1.

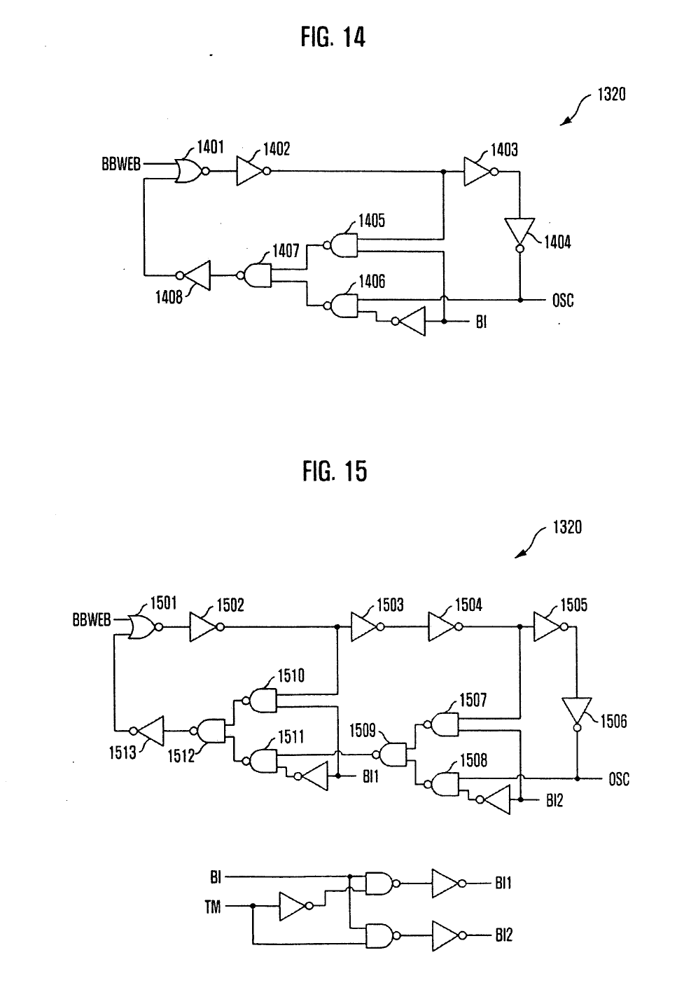

FIG. 14 is a schematic diagram depicting a first embodiment of the oscillation unit 1320 shown in FIG. 13.

The oscillation unit 1320 includes a plurality of delay units 1401 to 1408 connected in a ring form. Among the delay units 1401 to 1408, the number of delay units used for generating the oscillation signal OSC is determined according to the burn-in test signal BI.

When the burn-in test signal BI is deactivated as a low level, the NAND gate 1405 always outputs a high level signal and the NAND gate 1406 is operated as an inverter. Therefore, when the detection signal BBWEB is activated as a low level, the oscillation signal OSC is generated through the delay units 1401, 1402, 1403, 1404, 1406, 1407 and 1408. In other words, in a normal mode when the burn-in test signal BI is deactivated as a low level, the oscillation signal OSC is generated by using seven delay units 1401, 1402, 1403, 1404, 1406, 1407 and 1408.

When the burn-in test signal BI is activated as a high level, the NAND gate 1406 always outputs a high level signal and the NAND gate 1405 is operated as an inverter. Therefore, when the detection signal BBWEB is activated as a low level, the oscillation signal OSC is generated through the delay units 1401, 1402, 1405, 1407 and 1408. In other words, in the burn-in test mode when the burn-in test signal BI is activated as a high level, the oscillation signal OSC is generated by using five delay units 1401, 1402, 1405, 1407 and 1408.

When the oscillation signal OSC is generated through the seven delay units 1401, 1402, 1403, 1404, 1406, 1407 and 1408, the period of the oscillation signal OSC is lengthened in comparison with the oscillation signal OSC generated through the five delay units 1401, 1402, 1405, 1407 and 1408. Since the oscillation signal OSC is slow in toggling as the period of the oscillation signal OSC is lengthened, the oscillation signal OSC toggles faster in the burn-in test mode than in the normal mode, i.e., the frequency is increased.

FIG. 15 is a diagram depicting a second embodiment of the oscillation unit 1320 shown in FIG. 13.

The oscillation unit 1320 includes a plurality of delay units 1501 to 1513 connected in a ring form. Among the delay units 1501 to 1513, the number of delay units used for generating the oscillation signal OSC is determined according to the burn-in test signal BI and a test mode signal TM. In the first embodiment of the oscillation unit 1320, the period of the oscillation signal OSC is adjusted in two steps according to the activation/deactivation states of the burn-in test signal BI as above-mentioned. However, in the second embodiment of the oscillation unit 1320, the period of the oscillation signal OSC is adjusted in three steps according to the activation/deactivation states of the burn-in test signal BI and the activation/deactivation states of the test mode signal TM.

If the burn-in test signal BI is deactivated as a low level, all signals BI1 and BI2 are deactivated as a low level. Therefore, the NAND gates 1507 and 1510 always output a high level signal and the NAND gates 1508 and 1511 are operated as an inverter. Accordingly, when the detection signal BBWEB is activated as a low level, the oscillation signal OSC is generated through the delay units 1501, 1502, 1503, 1504, 1505, 1506, 1508, 1509, 1511, 1512 and 1513. That is, the oscillation signal OSC is generated by using eleven delay units.

When the burn-in test signal BI is activated as a high level and the test mode signal TM is activated as a high level, the signal BI1 is deactivated as a low level and the signal BI2 is activated as a high level. Accordingly, the NAND gates 1508 and 1510 always output a high level signal and the NAND gates 1507 and 1511 are operated as an inverter. Therefore, when the detection signal BBWEB is deactivated as a low level, the oscillation signal OSC is generated through the delay units 1501, 1502, 1503, 1504, 1507, 1509, 1511, 1512 and 1513, i.e., the oscillation signal OSC is generated by using nine delay units.

When the burn-in test signal BI is activated as a high level and the test mode signal TM is deactivated as a low level, the signal BI1 is activated as a high level and the signal BI2 is deactivated as a low level. Accordingly, the NAND gate 1511 always outputs a high level signal and the NAND gate 1510 is operated as an inverter. Therefore, when the detection signal BBWEB is deactivated as a low level, the oscillation signal OSC is generated through the delay units 1501, 1502, 1510, 1512 and 1513, i.e., the oscillation signal OSC is generated through 5 delay units.

Since the oscillation unit 1320 in accordance with the second embodiment adjusts the period of the oscillation signal OSC according to whether the internal voltage generating circuit is in the burn-in test mode or not and the activation/deactivation state of the test mode signal TM, the period of the oscillation signal OSC can be more variously adjusted than the first embodiment by using the oscillation unit 1320 in accordance with the second embodiment. It means that the speed of the pumping operation can be more variously adjusted.

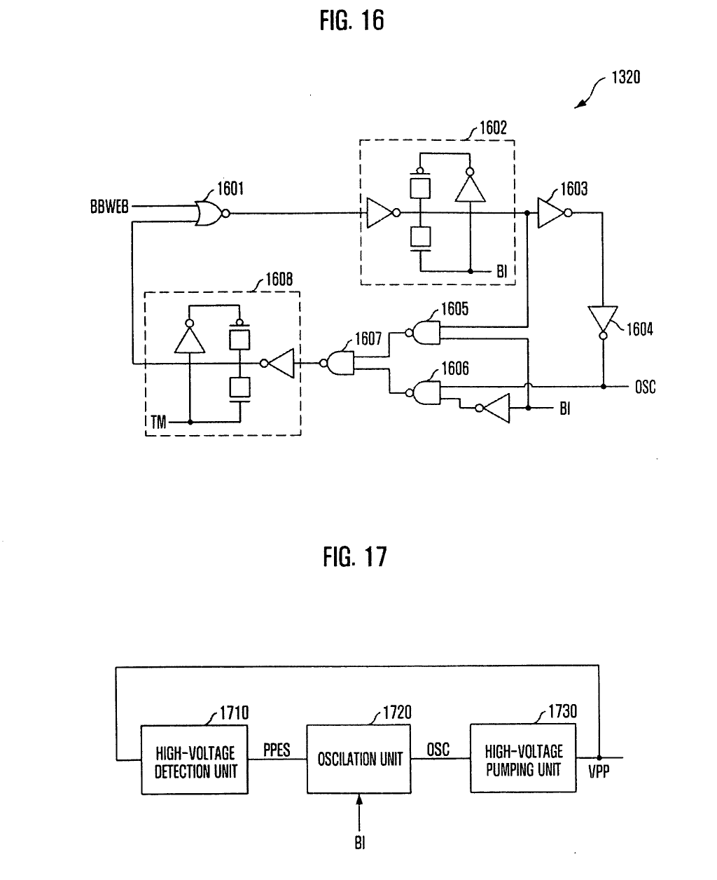

FIG. 16 is a diagram illustrating a third embodiment of the oscillation unit 1320 shown in FIG. 13.

In the previous embodiments, it has been explained that the period of the oscillation signal OSC is varied by changing the number of delay units 1601 to 1608 used for generating the oscillation signal OSC. In accordance with the third embodiment, it will be explained that a delay amount of the delay units 1602 and 1608 as well as the number of the delay units 1601 to 1608 is adjusted by the burn-in test signal BI and the test mode signal TM.

Each of the delay units 1602 and 1608 includes two capacitors therein. The capacitor of the delay unit 1602 is turned on/off according to a logic value of the burn-in test signal BI, and the capacitor of the delay unit 1608 is turned on/off according to a logic value of the test mode signal TM. Therefore, a delay amount of the delay unit 1602 is changed according to the burn-in test signal BI and a delay amount of the delay unit 1608 is changed according to the test mode signal TM.

The fact that the delay amount of the delay units 1602 to 1608 is changed by the burn-in test signal BI and the test mode signal TM means that the period of the oscillation signal OSC is changed by the burn-in test signal BI and the test mode signal TM.

Since it has already been explained how the number of the delay units 1601 to 1608 used for generating the oscillation signal OSC is changed by the burn-in test signal BI referring to the first embodiment, further detailed explanations are omitted herein.

FIG. 17 is a diagram showing an internal voltage generating circuit for generating a high voltage in accordance with an embodiment of the present invention.

Referring to FIG. 17, the internal voltage generating circuit includes a high-voltage detection unit 1710, an oscillation unit 1720 and a high-voltage pumping unit 1730.

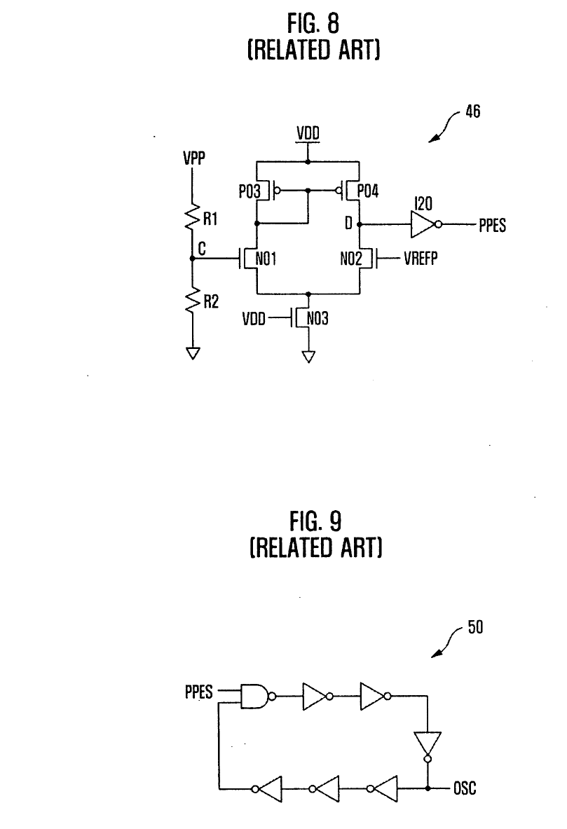

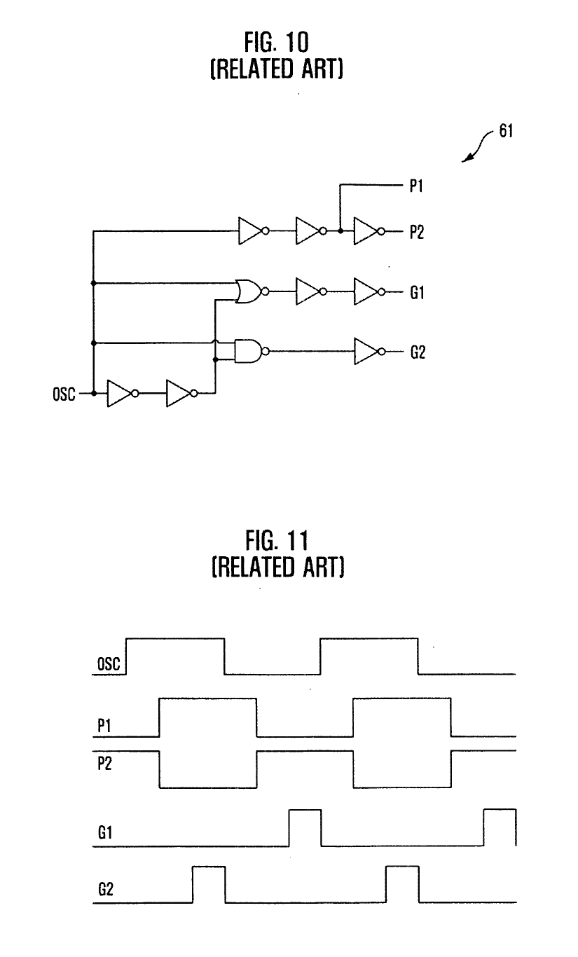

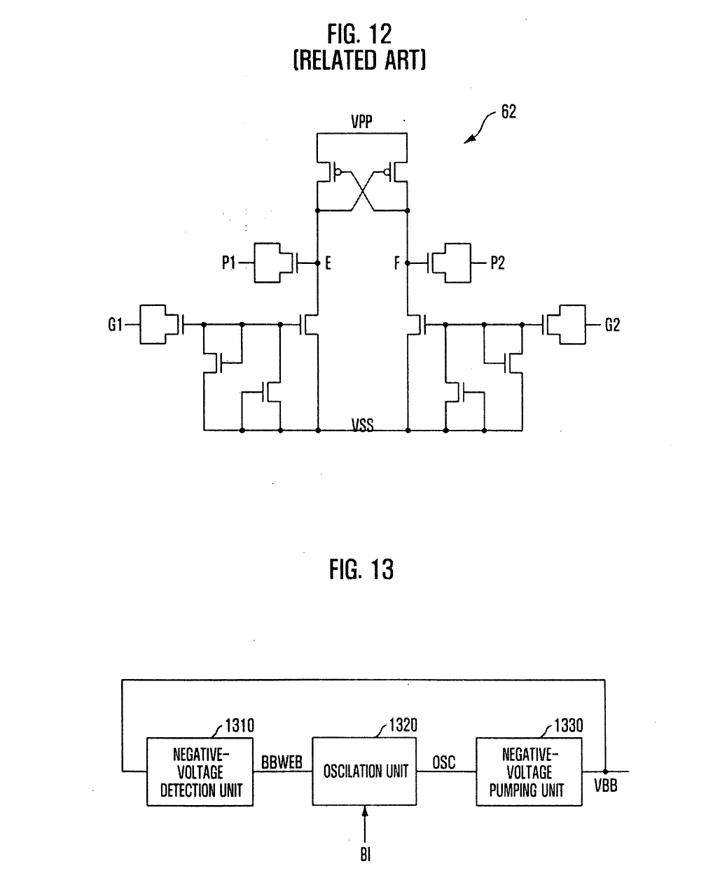

The high-voltage detection unit 1710 activates and outputs a detection signal PPES when the level of the high voltage is not sufficiently high. The activation of the detection signal PPES means that the oscillation signal OSC is outputted from the oscillation unit 1720 and the deactivation of the detection signal PPES means that the oscillation signal OSC is not outputted from the oscillation unit 1720. The high-voltage detection unit 1710 and the conventional high-voltage detection unit 40 shown in FIG. 7 can be similarly designed.

The high-voltage detection unit 1710 is employed to pump the high voltage VPP only when the internal voltage generating circuit is needed to pump the high voltage VPP. Therefore, if the internal voltage generating circuit is designed to always pump the high voltage VPP, the internal voltage generating circuit can be operated without the high-voltage detection unit 1710.

The oscillation unit 1720 outputs the oscillation signal OSC at the activation period of the detection signal PPES and does not output the oscillation signal OSC at the deactivation period of the detection signal PPES. The conventional oscillation unit 50 shown in FIG. 7 outputs the oscillation signal which keeps a constant period whenever the detection signal is activated. However, unlike the conventional oscillation unit, the oscillation unit in accordance with the present invention adjusts the period of the oscillation signal OSC according to whether the internal voltage generating circuit is in the burn-in test state or not.

In the burn-in test state, the oscillation signal OSC is adjusted to be fast, i.e., the frequency is increased and the period is shortened, so that the high voltage pumping operation can be fast performed. When not in the burn-in test state, the oscillation signal OSC is adjusted to be more slow, i.e., the frequency is decreased and the period is lengthened, than in the burn-in test state.

A construction of the oscillation unit 1720 is similar to that of the above-mentioned oscillation units shown in FIGS. 14 to 16. Herein, since the detection signal PPES is activated as a high level unlike the detection signal BBWEB, the NOR gate, e.g., 1401, 1501 and 1601, is replaced with a NAND gate and the detection signal PPES instead of the detection signal BBWEB is inputted to the oscillation unit 1720.

The high-voltage pumping unit 1730 generates a high voltage VPP in response to the oscillation signal OSC. The high voltage VPP is generated by performing the pumping operation and the speed of the pumping operation of the high voltage VPP is varied according to the period of the oscillation signal OSC. The high-voltage pumping unit 1730 and the conventional high-voltage pumping unit 60 shown in FIG. 7 can be similarly designed.

The internal voltage generating circuit in accordance with the present invention controls a speed of pumping operations according to whether it is in the burn-in state or nor. Therefore, the present invention has an advantage to supply stable pumping voltages VPP and VBB even in the burn-in state.

While the present invention has been described with respect to the specific embodiments, it will be apparent to those skilled in the art that various changes and modifications may be made without departing from the spirit and scope of the invention as defined in the following claims.

What is claimed is:

1. An internal voltage generating circuit, comprising:
an oscillation unit configured to generate an oscillation signal, and to change a period of the oscillation signal according to whether in a burn-in state; and
a negative voltage pumping unit configured to generate a negative voltage in response to the oscillation signal.

2. The internal voltage generating circuit of claim 1, wherein the oscillation unit includes a plurality of delay units connected in a ring form, and selects a number of the delay units, which are used for generating the oscillation signal, among the plurality of delay units according to a burn-in test signal.

3. The internal voltage generating circuit of claim 2, wherein the oscillation unit selects the number of the delay units according to both the burn-in test signal and a test mode signal.

4. The internal voltage generating circuit of claim 2, wherein the oscillation unit is responsive to a test mode signal to change a delay amount of at least one of the number of delay units.

5. The internal voltage generating circuit of claim 1, wherein the oscillation unit includes a plurality of delay units connected in a ring form, and is responsive to a burn-in test signal to change a delay amount of at least one of the plurality of delay units.

6. The internal voltage generating circuit of claim 5, wherein the at least one of the plurality of delay units includes at least one capacitor, and is responsive to the burn-in test signal to turn on/off the at least one capacitor.

7. The internal voltage generating circuit of claim 1, further comprising a negative voltage detection unit configured to detect a level of the negative voltage, and to generate a detection signal based on a result of the detection for activation/deactivation of the oscillation unit.

8. The internal voltage generating circuit of claim 7, wherein the negative voltage detection unit includes a transistor that receives the negative voltage, and generates the detection signal using a resistance change of the transistor.

9. The internal voltage generating circuit of claim 1, wherein the negative voltage pumping unit includes:
a pumping control unit configured to generate a pumping control signal in response to the oscillation signal; and
a charge pumping unit configured to generate the negative voltage in response to the pumping control signal.

10. The internal voltage generating circuit of claim 1, wherein the negative voltage pumping unit generates the negative voltage according to the period of the oscillation signal.

11. An internal voltage generating circuit, comprising:
an oscillation unit configured to generate an oscillation signal, and to change a period of the oscillation signal according to whether is in a burn-in test state; and
a high voltage generation unit configured to generate a high voltage higher than a power supply voltage in response to the oscillation signal.

12. The internal voltage generating circuit of claim 11, wherein the oscillation unit includes a plurality of delay units connected in a ring form, and selects a number of the delay units, which are used for generating the oscillation signal, among the plurality of delay units according to a burn-in test signal.

13. The internal voltage generating circuit of claim 12, wherein the oscillation unit selects the number of delay units according to both the burn-in test signal and a test mode signal.

14. The internal voltage generating circuit of claim 12, wherein the oscillation unit is responsive to a test mode signal to change a delay amount of at least one of the plurality of delay units.

15. The internal voltage generating circuit of claim 11, wherein the oscillation unit includes a plurality of delay units connected in a ring form, and is responsive to a burn-in test signal to change a delay amount of at least one of the plurality of delay units.

16. The internal voltage generating circuit of claim 15, wherein the at least one of the plurality of delay units includes at least one capacitor, and is responsive to the burn-in test signal to turn on/off the at least one capacitor.

17. The internal voltage generating circuit of claim 11, further comprising a high voltage detection unit configured to detect a level of the high voltage, and to generate a detection signal based on a result of the detection for activation/deactivation of the oscillation unit.

18. The internal voltage generating circuit of claim 17, wherein the high voltage detection unit includes:
a voltage division unit configured to divide the high voltage and output the divided voltage; and
a comparison unit configured to compare the divided voltage with a reference voltage in order to generate the detection signal.

19. The internal voltage generating circuit of claim 11, wherein the high voltage pumping unit includes:
a pumping control unit configured to generate a pumping control signal in response to the oscillation signal; and
a charge pumping unit configured to generate the high voltage in response to the pumping control signal.

20. The internal voltage generating circuit of claim 11, wherein the high voltage generation unit generates the high voltage according to the period of the oscillation signal.
